(19) United States
(12) Patent Application Publication
(10) Pub. No.: US 2026/0077390 A1
(43) Pub. Date: Mar. 19, 2026

(54) SUBSTRATE PROCESSING DEVICE AND SUBSTRATE PROCESSING METHOD

(71) Applicant: SCREEN Holdings Co., Ltd., Kyoto (JP)

(72) Inventors: Kyosuke MURATA, Kyoto (JP); Daiki FUJII, Kyoto (JP); Tomohiro TAKAHASHI, Kyoto (JP)

(21) Appl. No.: 19/317,008

(22) Filed: Sep. 2, 2025

(30) Foreign Application Priority Data
Sep. 13, 2024 (JP) 2024-159546

(51) Int. Cl. B08B 3/10; B08B 3/04; B08B 3/08; B08B 13/00; H01L 21/67

(52) U.S. Cl. CPC B08B 3/10; B08B 3/048; B08B 3/08; B08B 13/00; H10P 72/0416

(57) ABSTRACT

Processing unevenness within a substrate surface is further suppressed even in a case where an upward flow rate increases. A substrate processing device includes a controller that controls, on the basis of a flow rate of a processing liquid which is controlled by a second flow rate control mechanism, a first flow rate control mechanism so that a flow rate of gas supplied to a first gas supply pipe is larger than a flow rate of gas supplied to a second gas supply pipe.

This Nonprovisional application claims priority under 35 U.S.C. § 119 on Patent Application No. 2024-159546 filed in Japan on Sep. 13, 2024, the entire contents of which are hereby incorporated by reference.

### TECHNICAL FIELD

The present invention relates to a substrate processing device and a substrate processing method.

### BACKGROUND ART

It is known that substrates that are used for electronic parts such as semiconductor devices and liquid crystal display devices are processed by a substrate processing device. The substrates can be processed by immersion in a processing liquid in a process tank.

There is an increasing demand for uniformly processing substrates, in accordance with miniaturization and/or a shift to a three-dimensional structure of semiconductor elements formed on semiconductor substrates in recent years. For example, a NAND element having a three-dimensional structure has a laminated structure in which a three-dimensional relief structure is provided. In a case where a processing liquid is retained in a recess of a relief structure of an element pattern, liquid displacement in the recess becomes insufficient. On this account, in order to promote sufficient liquid displacement all over a substrate including such a recess, a gas bubble generation pipe may be provided below a substrate that is immersed in a process tank. Then, liquid displacement may be promoted in the process tank by generating gas bubbles from the gas bubble generation pipe.

In such a technology, in order to prevent processing unevenness within a substrate surface in the process tank, for example, as indicated by Patent Literature 1, a technology has been developed in which flow rates of gas supplied to a plurality of gas bubble generation pipes are set such that the flow rate to an outer gas bubble generation pipe is larger than the flow rate to an inner gas bubble generation pipe.

### CITATION LIST

### Patent Literature

### Patent Literature 1

Japanese Patent Application Publication Tokukai No. 2022-73306

### SUMMARY OF INVENTION

### Technical Problem

In the process tank, a plurality of liquid discharge pipes are also provided. The liquid discharge pipes discharge a processing liquid and thus generate an upward flow that moves upward inside the process tank. In a process of diligently advancing development of a technology for preventing processing unevenness within a substrate surface in the above-described process tank, the inventors of the present invention have found that in a case where an upward flow rate is large, gas bubbles in the process tank flow toward a central part of the process tank. In a case where such deviation of the gas bubbles occurs, the possibility of the occurrence of processing unevenness within a substrate surface cannot be eliminated.

An object of an aspect of the present invention is to further suppress processing unevenness within a substrate surface even in a case where an upward flow rate increases.

### Solution to Problem

In order to solve the above problem, a substrate processing device according to an aspect of the present invention includes: a substrate holder that holds at least one substrate; a process tank that stores a processing liquid for immersing therein the substrate held by the substrate holder; an outer gas bubble generation pipe that is located below a peripheral region of the substrate and that generates gas bubbles in the processing liquid by supplying gas in the processing liquid; an inner gas bubble generation pipe that is located below a central region of the substrate and that generates gas bubbles in the processing liquid by supplying gas in the processing liquid; a first gas supply pipe that connects a gas supply source and the outer gas bubble generation pipe to each other; a second gas supply pipe that connects the gas supply source and the inner gas bubble generation pipe to each other; a plurality of liquid discharge pipes that, by discharging the processing liquid into the process tank, generate an upward flow which moves upward inside the process tank; a plurality of liquid supply pipes that are connected to the plurality of liquid discharge pipes; a first flow rate control mechanism that controls flow rates of gas which is flowing in the first gas supply pipe and the second gas supply pipe; a second flow rate control mechanism that controls a flow rate of the processing liquid which is supplied to the plurality of liquid supply pipes; and a controller that controls the first flow rate control mechanism and the second flow rate control mechanism, the controller controlling, on the basis of the flow rate of the processing liquid which is controlled by the second flow rate control mechanism, the first flow rate control mechanism so that the flow rate of gas supplied to the first gas supply pipe is larger than the flow rate of gas supplied to the second gas supply pipe.

A substrate processing method in accordance with an aspect of the present invention includes: immersing a substrate in a processing liquid which is stored in a process tank; generating gas bubbles in the processing liquid by supplying gas to (i) an outer gas bubble generation pipe that is located below a peripheral region of the substrate which is placed in the process tank and (ii) an inner gas bubble generation pipe that is located below a central region of the substrate, and supplying the gas bubbles to the substrate which is immersed in the processing liquid; and supplying the processing liquid to a plurality of liquid discharge pipes that discharge the processing liquid in the process tank, in order to generate an upward flow which moves upward inside the process tank, the supplying the gas bubbles including performing, on the basis of a flow rate of the processing liquid which is supplied to the plurality of liquid discharge pipes, gas flow rate adjustment so that a flow rate of gas supplied to the outer gas bubble generation pipe is larger than a flow rate of gas supplied to the inner gas bubble generation pipe.

### Advantageous Effects of Invention

A substrate processing device and the like in accordance with an aspect of the present invention makes it possible to further suppress processing unevenness within a substrate surface even in a case where an upward flow rate increases.

### BRIEF DESCRIPTION OF DRAWINGS

FIG. 1 is a perspective view illustrating an example of an outline configuration of a substrate processing device in accordance with an embodiment of the present invention.

FIG. 2 is a schematic diagram illustrating a state in which gas bubbles are generated in an inner tank of a process tank that is provided in the substrate processing device illustrated in FIG. 1.

FIG. 3 is a top view of the substrate processing device illustrated in FIG. 1.

FIG. 4 is a schematic diagram illustrating an outline configuration surrounding the process tank in the substrate processing device illustrated in FIG. 1.

FIG. 5 is a schematic diagram illustrating a flow of a processing liquid in an inner tank of the process tank that is provided in the substrate processing device illustrated in FIG. 1.

FIG. 6 is a flowchart illustrating an example of a process of a substrate processing method which is carried out by the substrate processing device illustrated in FIG. 1.

### DESCRIPTION OF EMBODIMENTS

### (Configuration of Substrate Processing Device 100)

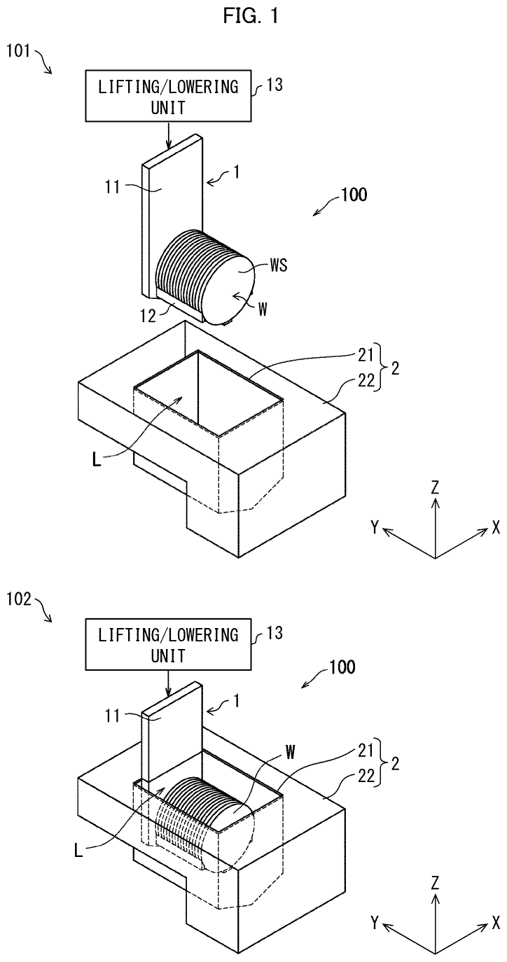

FIG. 1 is a perspective view illustrating an example of an outline configuration of a substrate processing device 100 in accordance with an embodiment of the present invention. Note that in FIGS. 1 to 5, a direction in which a plurality of outer gas bubble generation pipes 31 and 32 are aligned is defined as an X axis direction, a direction in which a plurality of substrates W are arranged is defined as a Y axis direction, and a direction in which a lifting/lowering unit 13 lifts/lowers a substrate holder 1 is defined as a Z axis direction. The X axis direction, the Y axis direction, and the Z axis direction are orthogonal to each other.

As shown in a drawing indicated by reference sign 101 in FIG. 1, the substrate processing device 100 includes a substrate holder 1 and a process tank (process bath) 2. The substrate processing device 100 processes at least one substrate W. Specifically, the substrate processing device 100 processes the substrate W so as to carry out, with respect to the substrate W, at least one selected from the group consisting of etching, surface processing, addition of a characteristic, formation of a processing film, removal of at least part of a film, removal of impurities, and cleaning.

Examples of the impurities to be removed by the substrate processing device 100 include fine particles, metal, residues, and organic substances such as photoresists which have adhered to a surface of the substrate W. Examples of the film to be removed by the substrate processing device 100 include natural oxide films and nitride films which have been formed on a surface of the substrate W.

The substrate W has a thin plate-like shape, and has, for example, a thin substantially circular shape. Note that in the present specification, the word “substantially” has a concept that is not limited to a case of being exactly same but that includes a case involving an error and/or deformation to an extent at which identity is not lost. Examples of the substrate W include semiconductor wafers, liquid crystal display substrates, plasma display substrates, and field emission display (FED) substrates. Further, examples of the substrate W include optical disc substrates, magnetic disc substrates, magneto-optic disc substrates, photomask substrates, ceramic substrates, and solar cell substrates.

The substrate processing device 100 is a so-called batch-type processing device capable of processing, in a batch, a lot that includes a plurality of substrates W. However, the substrate processing device 100 may process the substrates W one by one.

The substrate processing device 100 processes the substrates W with use of a processing liquid L. The processing liquid L is a cleaning liquid for cleaning surfaces of the substrates W. The processing liquid L preferably contains a phosphoric acid liquid. In this case, the substrate processing device 100 removes a nitride film that is formed on the surfaces of the substrates W.

Note that the processing liquid L may be a liquid mixture of sulfuric acid and hydrogen peroxide water (sulfuric acid-hydrogen peroxide mixture (SPM)) or a liquid mixture of ammonium hydroxide and hydrogen peroxide water (ammonia hydrogen peroxide mixture (APM)). Further, the processing liquid L may be a liquid mixture of hydrochloric acid and hydrogen peroxide water (hydrochloric acid-hydrogen peroxide mixture (HPM)) or a processing liquid that contains a diluted hydrofluoric acid (DHF).

In addition, the processing liquid L may be a liquid mixture of a hydrofluoric acid and hydrogen peroxide water (hydrofluoric peroxide mixture (FPM)) or a liquid mixture of ammonium fluoride and a hydrofluoric acid (buffered hydrogen fluoride (BHF)).

### (Configurations of Substrate Holder 1 and Process Tank 2)

The substrate holder 1 holds at least one substrate W. A normal direction of a main surface WS of the substrate W which is held by the substrate holder 1 is the Y axis direction. A plurality of substrates W are arranged in a row along the Y axis direction. In other words, the plurality of substrates W are each arranged so as to be substantially parallel to an XZ plane. Further, the plurality of substrates W each extend in the X axis direction and the Z axis direction.

The substrate holder 1 is specifically a lifter, and includes a back board 11, mounting parts 12, and a lifting/lowering unit 13. The back board 11 extends in the XZ plane. The mounting parts 12 are made of, for example, holding rods that extend in a negative direction of the Y axis from one surface of the back board 11. For example, three mounting parts 12 extend in the negative direction of the Y axis from the one surface of the back board 11. The mounting parts 12 abut on a lower edge of each of a plurality of substrates W in a state in which the plurality of substrates W are aligned at predetermined intervals. Thus, the mounting parts 12 hold the plurality of substrates W and mount the plurality of substrates W.

The lifting/lowering unit 13 lifts/lowers the substrate holder 1 in the Z axis direction. The lifting/lowering unit 13 moves the substrate holder 1 in a negative direction of the Z axis. As a result, as shown in a drawing indicated by reference sign 102 in FIG. 1, the plurality of substrates W that are held by the substrate holder 1 are immersed in the processing liquid L that is stored in the process tank 2.

The process tank 2 stores the processing liquid L for immersing therein the substrates W which are held by the substrate holder 1. The process tank 2 has a double tank structure that includes an inner tank 21 and an outer tank 22. Each of the inner tank 21 and the outer tank 22 has an upper opening that opens upward. The inner tank 21 stores therein the processing liquid L, and is configured to be capable of accommodating the plurality of substrates W. The outer tank 22 is provided outside the inner tank 21. The outer tank 22 stores the processing liquid L which overflows from the inner tank 21.

### (Configurations of Outer Gas Bubble Generation Pipes, Inner Gas Bubble Generation Pipes, and Liquid Discharge Pipes)

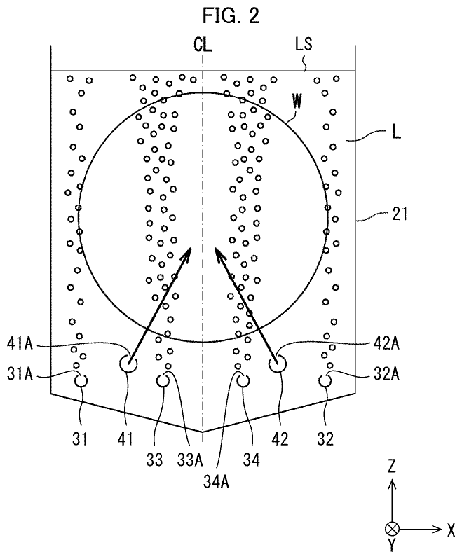

FIG. 2 is a schematic diagram illustrating a state in which gas bubbles are generated in the inner tank 21 of the process tank 2 that is provided in the substrate processing device 100 illustrated in FIG. 1. In FIG. 2, illustration of the substrate holder 1 is omitted. As illustrated in FIG. 2, the substrate processing device 100 includes a plurality of outer gas bubble generation pipes 31 and 32, a plurality of inner gas bubble generation pipes 33 and 34, and a plurality of liquid discharge pipes 41 and 42.

The outer gas bubble generation pipes 31 and 32 are located below a peripheral region of the substrate W that is disposed in the inner tank 21, and generate gas bubbles in the processing liquid L by supplying gas to the processing liquid L. The peripheral region of the substrate W as viewed from the Y axis direction is, for example, a region from (a) a position which is on the substrate W and from which a distance to a center of the substrate W along a direction parallel to the main surface WS of the substrate W is 0.6 times a radius of the substrate W to (b) an end of the substrate W.

The inner gas bubble generation pipes 33 and 34 are located below a central region of the substrate W that is disposed in the inner tank 21, and generate gas bubbles in the processing liquid L by supplying gas to the processing liquid L. The central region of the substrate W as viewed from the Y axis direction is a region of the substrate W excluding the peripheral region of the substrate and, for example, a region from (a) the center of the substrate W to (b) the position which is on the substrate W and from which the distance to the center of the substrate W along the direction parallel to the main surface WS of the substrate W is 0.6 times the radius of the substrate W. The inner gas bubble generation pipes 33 and 34 are located closer to the center of the substrate W than the outer gas bubble generation pipes 31 and 32, when viewed from the Y axis direction.

Gas bubbles that have been generated in the processing liquid L by the outer gas bubble generation pipes 31 and 32 and the inner gas bubble generation pipes 33 and 34 move upward in the processing liquid L and reach a liquid surface LS of the processing liquid L in the inner tank 21. The liquid surface LS of the processing liquid L is an interface between the processing liquid L in the inner tank 21 and gas such as air or a predetermined atmosphere. While the gas bubbles are moving upward in the processing liquid L, the gas bubbles come into contact with the surface of the substrate W.

The liquid discharge pipes 41 and 42 generate an upward flow that moves upward inside the inner tank 21, by discharging the processing liquid L into the inner tank 21. The liquid discharge pipes 41 and 42 discharge the processing liquid L in directions indicated by arrows in FIG. 2. That is, the liquid discharge pipes 41 and 42 discharge the processing liquid L in a positive direction (a direction from a negative side to a positive side) of the Z axis and toward an imaginary center line CL which extends in the Z axis direction through the center of the substrate W, when viewed from the Y axis direction. Note that the direction in which the processing liquid L is discharged by the liquid discharge pipes 41 and 42 is not limited to this.

As viewed from the Y axis direction, the liquid discharge pipes 41 and 42 are each disposed between the outer gas bubble generation pipe 31, 32 and the inner gas bubble generation pipe 33, 34. More specifically, as viewed from the Y axis direction, the liquid discharge pipe 41 is disposed between the outer gas bubble generation pipe 31 and the inner gas bubble generation pipe 33 in the X axis direction, and further, the liquid discharge pipe 42 is disposed between the outer gas bubble generation pipe 32 and the inner gas bubble generation pipe 34 in the X axis direction.

### (Configuration of Upper Surface Side of Substrate Processing Device 100)

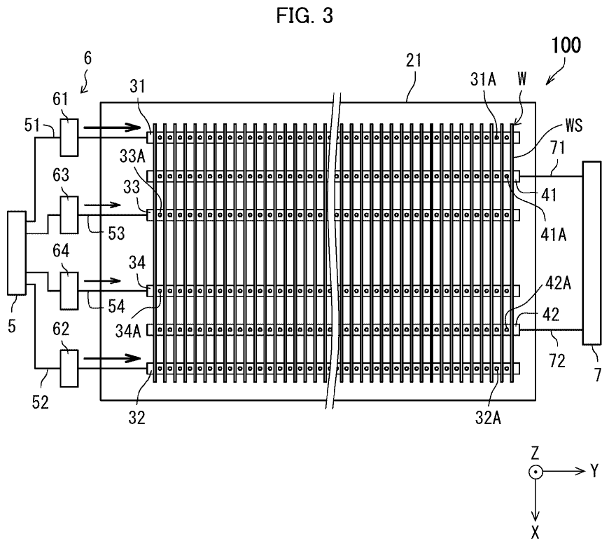

FIG. 3 is a top view of the substrate processing device 100 illustrated in FIG. 1. In FIG. 3, the substrate holder 1 and the outer tank 22 are omitted. As illustrated in FIG. 3, a plurality of substrates W are arranged at equal intervals in a row in the Y axis direction. For example, a distance between adjacent substrates W is 2 mm or more and 20 mm or less.

The outer gas bubble generation pipes 31 and 32, the inner gas bubble generation pipes 33 and 34, and the liquid discharge pipes 41 and 42 are located on a negative side in the Z axis direction of the substrates W that are held by the substrate holder 1. For example, the outer gas bubble generation pipes 31 and 32, the inner gas bubble generation pipes 33 and 34, and the liquid discharge pipes 41 and 42 are located in the vicinity of a bottom surface of the inner tank 21. The outer gas bubble generation pipes 31 and 32, the inner gas bubble generation pipes 33 and 34, and the liquid discharge pipes 41 and 42 extend in the Y axis direction and also in parallel to each other.

As illustrated in FIGS. 2 and 3, a plurality of discharge holes 31A for discharging gas are formed in the outer gas bubble generation pipe 31, and the plurality of discharge holes 31A are arranged at equal intervals in a row in the Y axis direction. The intervals of the plurality of discharge holes 31A are substantially the same as the intervals of the substrates W. The plurality of discharge holes 31A are located between the substrates W, when viewed from the Z axis direction.

In the same manner as the outer gas bubble generation pipe 31, a plurality of discharge holes 32A are formed in the outer gas bubble generation pipe 32, a plurality of discharge holes 33A are formed in the inner gas bubble generation pipe 33, and a plurality of discharge holes 34A are formed in the inner gas bubble generation pipe 34. Further, in the same manner as the outer gas bubble generation pipe 31, a plurality of discharge holes 41A are formed in the liquid discharge pipe 41, and a plurality of discharge holes 42A are formed in the liquid discharge pipe 42. Respective diameters and respective intervals of the plurality of discharge holes 31A to 34A and the plurality of discharge holes 41A and 42A are substantially equal to each other.

The outer gas bubble generation pipes 31 and 32 and the inner gas bubble generation pipes 33 and 34 are preferably made of, for example, a material that contains quartz. In this case, it is possible to make gas bubbles that are generated from each of the outer gas bubble generation pipes 31 and 32 and the inner gas bubble generation pipes 33 and 34 less easily contact with each other. This makes it possible to uniformly spread the gas bubbles all over surfaces of the substrates W. Note that the outer gas bubble generation pipes 31 and 32 and the inner gas bubble generation pipes 33 and 34 may be made of a material that contains polyether ether ketone (PEEK).

In a case where the outer gas bubble generation pipes 31 and 32 and the inner gas bubble generation pipes 33 and 34 are made of a material that contains quartz, each of the plurality of discharge holes 31A to 34A and the plurality of discharge holes 41A and 42A has a diameter of, for example, 0.26 mm. Further, in a case where the outer gas bubble generation pipes 31 and 32 and the inner gas bubble generation pipes 33 and 34 are made of a material that contains PEEK, each of the plurality of discharge holes 31A to 34A and the plurality of discharge holes 41A, 42A has a diameter of, for example, 0.2 mm. However, the diameter of each of the plurality of discharge holes 31A to 34A and the plurality of discharge holes 41A and 42A are not limited to the above-described diameters.

The substrate processing device 100 includes a gas supply source 5, a first flow rate control mechanism 6, a second flow rate control mechanism 7, a plurality of first gas supply pipes 51 and 52, a plurality of second gas supply pipes 53 and 54, and a plurality of liquid supply pipes 71 and 72. The first gas supply pipe 51 connects the gas supply source 5 and the outer gas bubble generation pipe 31 to each other, and the first gas supply pipe 52 connects the gas supply source 5 and the outer gas bubble generation pipe 32 to each other. The second gas supply pipe 53 connects the gas supply source 5 and the inner gas bubble generation pipe 33 to each other, and the second gas supply pipe 54 connects the gas supply source 5 and the inner gas bubble generation pipe 34 to each other.

The liquid supply pipes 71 and 72 are connected to the liquid discharge pipes 41 and 42, respectively. Specifically, the liquid supply pipe 71 connects the second flow rate control mechanism 7 and the liquid discharge pipe 41 to each other, and the liquid supply pipe 72 connects the second flow rate control mechanism 7 and the liquid discharge pipe 42 to each other.

The gas supply source 5 stores gas, and supplies the gas to the outer gas bubble generation pipe 31 via the first gas supply pipe 51 and also supplies the gas to the outer gas bubble generation pipe 32 via the first gas supply pipe 52. Further, the gas supply source 5 supplies the gas to the inner gas bubble generation pipe 33 via the second gas supply pipe 53 and also supplies the gas to the inner gas bubble generation pipe 34 via the second gas supply pipe 54. The gas supplied by the gas supply source 5 is, for example, nitrogen.

The first flow rate control mechanism 6 includes a plurality of first flow rate control mechanisms 61, 62, 63, and 64, and controls flow rates of gas that flows in the first gas supply pipes 51 and 52 and the second gas supply pipes 53 and 54.

The first flow rate control mechanism 61 is provided in the first gas supply pipe 51, and controls the flow rate of gas that flows in the first gas supply pipe 51. The first flow rate control mechanism 61 includes, for example, an adjustment valve (not illustrated) that adjusts the flow rate of gas that flows in the first gas supply pipe 51. The adjustment valve includes: a valve body (not illustrated) inside of which a valve seat is provided; a valve element (not illustrated) which opens and closes the valve seat; and an actuator (not illustrated) that moves the valve element between an open position and a closed position.

The first flow rate control mechanism 62 is provided in the first gas supply pipe 52, and controls the flow rate of gas that flows in the first gas supply pipe 52. Further, the first flow rate control mechanism 63 is provided in the second gas supply pipe 53, and controls the flow rate of gas that flows in the second gas supply pipe 53. The first flow rate control mechanism 64 is provided in the second gas supply pipe 54, and controls the flow rate of gas that flows in the second gas supply pipe 54. Each of the first flow rate control mechanisms 62 to 64 includes an adjustment valve in the same manner as the first flow rate control mechanism 61.

The second flow rate control mechanism 7 is located outside the process tank 2 and controls a flow rate of the processing liquid L which is supplied to the liquid supply pipes 71 and 72. The processing liquid L flows from the second flow rate control mechanism 7 to the liquid discharge pipe 41 via the liquid supply pipe 71, and also from the second flow rate control mechanism 7 to the liquid discharge pipe 42 via the liquid supply pipe 72. Note that the second flow rate control mechanism 7 may circulate and use a liquid that has once been used as the processing liquid L in the process tank 2. The flow rate of the processing liquid L that is supplied to each of the liquid supply pipes 71 and 72 is, for example, 40 L/min or less, or 100 L/min or less.

### (Configuration Surrounding Process Tank 2)

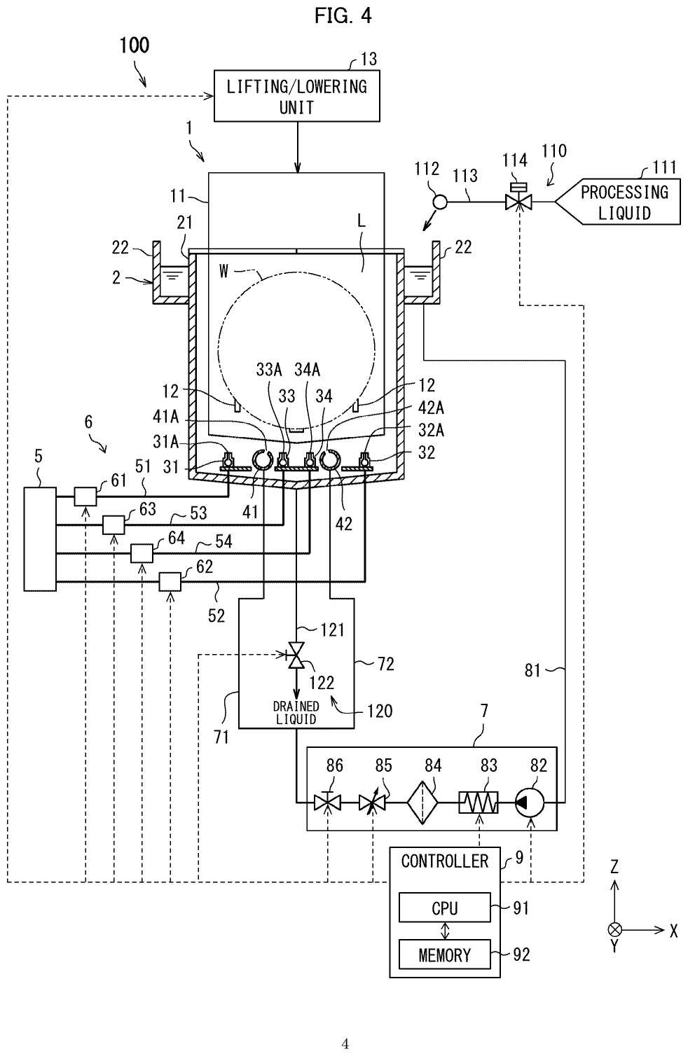

FIG. 4 is a schematic diagram illustrating an outline configuration surrounding the process tank 2 in the substrate processing device 100 illustrated in FIG. 1. The second flow rate control mechanism 7 circulates the processing liquid L which is stored in the process tank 2 and supplies the processing liquid L to the liquid supply pipes 71 and 72. The second flow rate control mechanism 7 includes a pipe 81, a pump 82, a heater 83, a filter 84, an adjustment valve 85, and a valve 86. The pump 82, the heater 83, the filter 84, the adjustment valve 85, and the valve 86 are arranged in this order from upstream to downstream of the pipe 81.

The pipe 81 guides, to the liquid supply pipes 71 and 72, the processing liquid L that has been drained from the outer tank 22. The pipe 81 not only connects the outer tank 22 and liquid supply pipes 71 and 72 with each other but also branches into the liquid supply pipes 71 and 72. The pump 82 sends the processing liquid L from the outer tank 22 to the liquid supply pipes 71 and 72. The heater 83 adjusts a temperature of the processing liquid L by heating the processing liquid L that is flowing in the pipe 81. The filter 84 filters the processing liquid L that is flowing in the pipe 81.

The adjustment valve 85 adjusts the flow rate of the processing liquid L which is supplied to the liquid supply pipes 71 and 72. More specifically, the adjustment valve 85 includes: a valve body (not illustrated) inside of which a valve seat is provided; a valve element (not illustrated) which opens and closes the valve seat; and an actuator (not illustrated) which moves the valve element between an open position and a closed position. The valve 86 opens and closes a flow channel from the pipe 81 to the liquid supply pipes 71 and 72.

The substrate processing device 100 includes a processing liquid supply part 110. The processing liquid supply part 110 supplies the processing liquid L to the process tank 2. The processing liquid supply part 110 includes a processing liquid supply source 111, a nozzle 112, a pipe 113, and a valve 114.

The processing liquid supply source 111 supplies the processing liquid L to the pipe 113. The nozzle 112 connects with the pipe 113 and discharges the processing liquid L into the process tank 2. The valve 114 is provided in the pipe 113 and opens and closes a flow channel of the pipe 113. When the valve 114 is opened, the processing liquid L which is discharged by the nozzle 112 is supplied into the process tank 2.

The substrate processing device 100 includes a liquid drainage part 120. The liquid drainage part 120 drains the processing liquid L which is stored in the inner tank 21. The liquid drainage part 120 includes a liquid drainage pipe 121 and a valve 122. The inner tank 21 has a bottom wall which is connected to the liquid drainage pipe 121. The valve 122 is provided in the liquid drainage pipe 121. In a case where the valve 122 is opened, the processing liquid L which is stored in the inner tank 21 is drained to outside of the process tank 2 through the liquid drainage pipe 121. The processing liquid L drained is sent to a drained liquid treatment device (not illustrated) and treated.

The substrate processing device 100 includes a controller (control section) 9. The controller 9 includes: a central processing unit (CPU) 91 that serves as a processor; and a memory 92. Note that the controller 9 may include, as the processor, for example, a micro processing unit (MPU), a graphic processing unit (GPU), an application specific integrated circuit (ASIC) or a field programmable gate array (FPGA). Further, the controller 9 may include, as the processor, a digital signal processor (DSP), a data flow processor (DFP), or a neural processing unit (NPU).

The memory 92 may be one or more hard disks (HDs), one or more random access memories (RAMs), one or more read only memories (ROMs), or one or more storage devices of a distributed computing system. Further, the memory 92 may be an optical disc (for example, a compact disc (CD), a digital versatile disc (DVD) or a Blu-ray disc (BD, registered trademark)), a flash memory device, or a memory card.

The controller 9 controls various operations of the substrate processing device 100. For example, the controller 9 controls the first flow rate control mechanism 6, the second flow rate control mechanism 7, the lifting/lowering unit 13, the valve 114, and the valve 122.

With regard to control of the first flow rate control mechanism 6 and the second flow rate control mechanism 7, specifically, the controller 9 controls each of the first flow rate control mechanisms 61 to 64, and also controls the pump 82, the heater 83, the adjustment valve 85, and the valve 86.

The controller 9 controls, on the basis of the flow rate of the processing liquid L which is controlled by the second flow rate control mechanism 7, the first flow rate control mechanism 6 so that the flow rates of gas supplied to the first gas supply pipes 51 and 52 are larger than the flow rates of gas supplied to the second gas supply pipes 53 and 54. This makes it possible to uniformly spread gas bubbles all over a surface of a substrate W. As a result, even in a case where an upward flow rate of the upward flow generated by the liquid discharge pipes 41 and 42 increases, it is possible to further suppress processing unevenness within the surface of the substrate W. Consequently, an improvement in yield can be expected. In addition, even in a case where the upward flow rate varies, gas bubbles can be uniformly spread all over the surface of the substrate W.

The controller 9 may acquire, from a motor (not illustrated) that is provided in the pump 82, a rotation speed of the motor, and may acquire, on the basis of the rotation speed of the motor, the flow rate of the processing liquid L which is controlled by the second flow rate control mechanism 7. Further, the controller 9 may be provided in the pipe 81, and may also acquire, from a flowmeter (not illustrated) that measures the flow rate of the processing liquid L flowing in the pipe 81, the flow rate of the processing liquid L which is controlled by the second flow rate control mechanism 7. The flowmeter may be provided in a part of the pipe 81 on a downstream side of the pump 82.

Further, the controller 9 is provided in the vicinity of an upper opening of the inner tank 21 and acquires a liquid pressure of the processing liquid L from a pressure sensor (not illustrated) that measures the liquid pressure of the processing liquid L which is stored in the inner tank 21. The controller 9 may obtain, on the basis of the liquid pressure of the processing liquid L which has been acquired, the flow rate of the processing liquid L which is controlled by the second flow rate control mechanism 7.

The controller 9 may control the first flow rate control mechanism 6 such that, as the flow rate of the processing liquid L which is controlled by the second flow rate control mechanism 7 increases, the difference between the flow rate of gas supplied to the first gas supply pipes 51 and 52 and the flow rate of gas supplied to the second gas supply pipe 53 and 54 increases.

Further, the controller 9 may carry out, on the basis of the flow rate of the processing liquid L which is controlled by the second flow rate control mechanism 7, feedback control of the first flow rate control mechanism 6 in real time. Specifically, the controller 9 may change, in real time, the flow rate of gas supplied to each of the first gas supply pipes 51 and 52 and the second gas supply pipes 53 and 54, in accordance with a change in the flow rate of the processing liquid L which is controlled by the second flow rate control mechanism 7.

The first flow rate control mechanism 6 controls an amount of gas bubbles generated from each of the outer gas bubble generation pipes 31 and 32 so that the amount is larger than that of gas bubbles generated from each of the inner gas bubble generation pipes 33 and 34. More specifically, the first flow rate control mechanisms 61 and 63 control the amount of gas bubbles generated from the outer gas bubble generation pipe 31 so that the amount is larger than that of gas bubbles generated from the inner gas bubble generation pipe 33. Moreover, the first flow rate control mechanisms 62 and 64 control the amount of gas bubbles generated from the outer gas bubble generation pipe 32 so that the amount is larger than that of gas bubbles generated from the inner gas bubble generation pipe 34.

Further, the controller 9 controls the first flow rate control mechanism 6, on the basis of the flow rate of the processing liquid L which is controlled by the second flow rate control mechanism 7, so that the amount of gas bubbles generated from each of the outer gas bubble generation pipes 31 and 32 is larger than the amount of gas bubbles generated from each of the inner gas bubble generation pipes 33 and 34.

In this case, each of the outer gas bubble generation pipes 31 and 32 generates a larger number of gas bubbles than each of the inner gas bubble generation pipes 33 and 34. Specifically, the outer gas bubble generation pipe 31 generates a larger number of gas bubbles than the inner gas bubble generation pipe 33, and the outer gas bubble generation pipe 32 generates a larger number of gas bubbles than the inner gas bubble generation pipe 34.

Note that the controller 9 preferably controls the first flow rate control mechanism 6 so that the flow rate of gas supplied to the first gas supply pipes 51 and 52 is substantially three times the flow rate of gas supplied to the second gas supply pipes 53 and 54. For example, the controller 9 preferably controls the first flow rate control mechanism 6 so that the flow rate of gas supplied to each of the first gas supply pipes 51 and 52 is 4.9 L/min and the flow rate of gas supplied to each of the second gas supply pipes 53 and 54 is 1.6 L/min.

Surface processing of the substrates W with use of the processing liquid L which includes a phosphoric acid liquid requires a longer time than surface processing of substrates W with use of a processing liquid which includes a chemical liquid other than a phosphoric acid liquid. Therefore, in a case where the controller 9 controls the first flow rate control mechanism 6 as described above, a further improvement in yield can be expected.

### (Flow of Processing Liquid L)

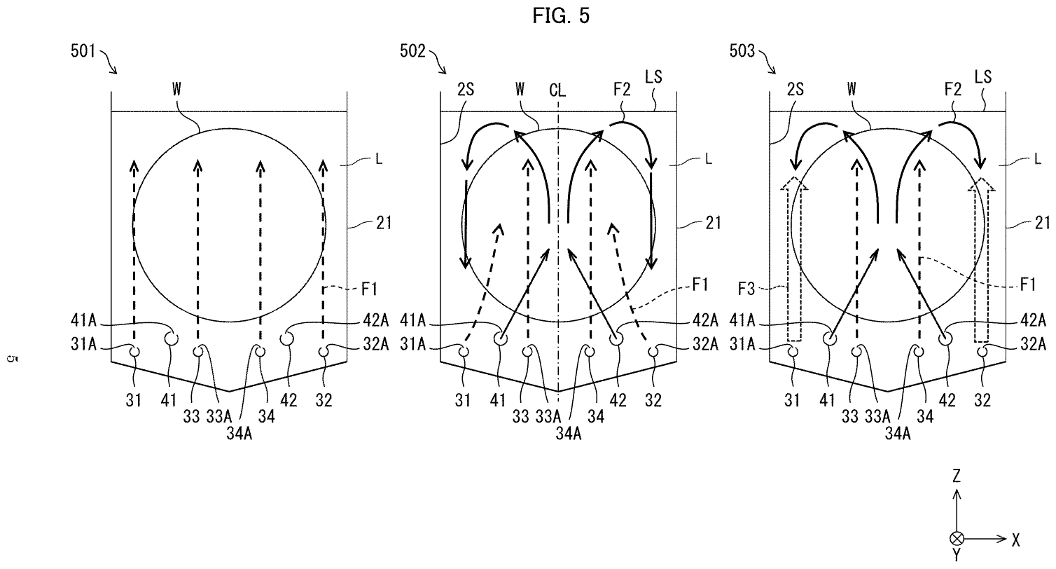

FIG. 5 is a schematic diagram illustrating a flow of the processing liquid L in the inner tank 21 of the process tank 2 that is provided in the substrate processing device 100 illustrated in FIG. 1. In drawings indicated by reference signs 501 to 503 of FIG. 5, dotted arrows each indicate a flow F1 of the processing liquid L which is caused by gas bubbles that are generated from the outer gas bubble generation pipes 31 and 32 and from the inner gas bubble generation pipes 33 and 34. Further, in those drawings, solid arrows each indicate a flow F2 of the processing liquid L which is generated by discharge of the processing liquid L by the liquid discharge pipes 41 and 42.

Assume a case where as shown in the drawing indicated by the reference sign 501 in FIG. 5, the outer gas bubble generation pipes 31 and 32 and the inner gas bubble generation pipes 33 and 34 supply gas to the processing liquid L in a state in which neither of the liquid discharge pipes 41 and 42 is discharging the processing liquid L into the inner tank 21. In this case, the flow F1 of the processing liquid L which is caused by the gas bubbles generated from the outer gas bubble generation pipes 31 and 32 and the inner gas bubble generation pipes 33 and 34 becomes a flow that moves in the positive direction of the Z axis. In the cases indicated by the reference signs 501 and 502 in FIG. 5, the flow rate of gas supplied to each of the first gas supply pipes 51 and 52 is 1.6 L/min and the flow rate of gas supplied to each of the second gas supply pipes 53 and 54 is 1.6 L/min.

Assume a case where, as shown in the drawing indicated by the reference sign 502 in FIG. 5, the liquid discharge pipes 41 and 42 are discharging the processing liquid L into the inner tank 21 and the flow rate of gas supplied to the outer gas bubble generation pipes 31 and 32 is substantially equal to that to the inner gas bubble generation pipes 33 and 34.

In this case, the liquid discharge pipes 41 and 42 generate an upward flow along an imaginary center line CL. Further, the flow F2 of the processing liquid L which is generated by the processing liquid L discharged by the liquid discharge pipes 41 and 42 becomes a flow that moves in the positive direction of the Z axis along the imaginary center line CL, and then, moves downward along a side surface 2S of the inner tank 21 after having reached a liquid surface LS of the processing liquid L in the inner tank 21. The side surface 2S is an inner surface that is substantially parallel to the YZ plane in the inner tank 21.

The flow F1 of the processing liquid L which is caused by gas bubbles generated from the inner gas bubble generation pipes 33 and 34 becomes a flow in the positive direction of the Z axis. Further, the flow F1 of the processing liquid L which is caused by gas bubbles generated from the outer gas bubble generation pipes 31 and 32 becomes a flow that moves in the positive direction of the Z axis along the imaginary center line CL due to a downward flow that is a portion of the flow F2 and that moves downward along the side surface 2S of the inner tank 21.

In other words, the flow F1 moves in the positive direction of the Z axis along the imaginary center line CL so as to avoid the downward flow that is a portion of the flow F2 and that moves downward from the liquid surface LS along the side surface 2S of the inner tank 21. Accordingly, the gas bubbles are unlikely to spread in the peripheral region of the substrate W. Note that the flow F1 changes according to the flow rate of the processing liquid L which is discharged by the liquid discharge pipes 41 and 42.

In light of the above, assume a case where, as shown in the drawing indicated by the reference sign 503 in FIG. 5, the liquid discharge pipes 41 and 42 are discharging the processing liquid L into the inner tank 21 and the flow rate of gas supplied to the processing liquid L by the outer gas bubble generation pipes 31 and 32 is larger than that by the inner gas bubble generation pipes 33 and 34. In this case, a flow F3 of the processing liquid L which is caused by the gas bubbles generated from the outer gas bubble generation pipes 31 and 32 is stronger than the flow F1 of the processing liquid L which is caused by the gas bubbles generated from the inner gas bubble generation pipes 33 and 34. Thus, the flow F3 becomes a flow that moves upward in the positive direction of the Z axis against the downward flow that is a portion of the flow F2 and that moves downward along the side surface 2S of the inner tank 21.

In the above-described manner, the upward flow that is generated by the liquid discharge pipes 41 and 42 results in generation of the downward flow along the side surface 2S of the inner tank 21, after having reached the liquid surface LS of the processing liquid L in the inner tank 21. The first flow rate control mechanism 6 controls the flow rate of gas supplied to each of the first gas supply pipes 51 and 52 so that gas bubbles generated by the outer gas bubble generation pipes 31 and 32 move upward against the downward flow.

Note that in the case indicated by the reference sign 503 in FIG. 5, the flow rate of gas supplied to each of the first gas supply pipes 51 and 52 is 4.9 L/min and the flow rate of gas supplied to each of the second gas supply pipes 53 and 54 is 1.6 L/min.

### (Substrate Processing Method)

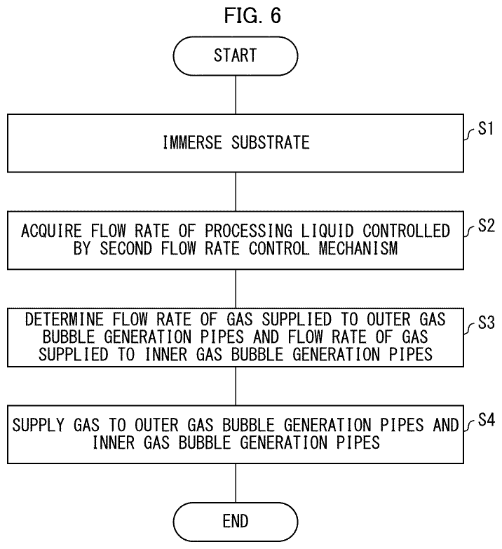

FIG. 6 is a flowchart illustrating an example of a process of a substrate processing method which is carried out by the substrate processing device 100 illustrated in FIG. 1. Here, the second flow rate control mechanism 7 supplies the processing liquid L to the plurality of liquid discharge pipes 41 and 42 which discharge the processing liquid L in the inner tank 21, in order to generate an upward flow which moves upward inside the inner tank 21.

While the second flow rate control mechanism 7 is supplying the processing liquid L, the lifting/lowering unit 13 lowers the substrate holder 1 that is holding a substrate W down to the inner tank 21 of the process tank 2, so that the substrate W is immersed in the processing liquid L which is stored in the inner tank 21, as shown in FIG. 6 (S1).

After the lifting/lowering unit 13 lowers the substrate holder 1, the controller 9 acquires the flow rate of the processing liquid L which is controlled by the second flow rate control mechanism 7 (S2). On the basis of the flow rate of the processing liquid L which has been acquired in S2, the controller 9 determines the flow rate of gas supplied to each of the outer gas bubble generation pipes 31 and 32 and the flow rate of gas supplied to each of the inner gas bubble generation pipes 33 and 34 (S3).

The gas supply source 5 supplies gas to each of the outer gas bubble generation pipes 31 and 32 and the inner gas bubble generation pipes 33 and 34 at the flow rate of gas which has been determined by the controller 9 in step S3, so that gas bubbles are generated in the processing liquid L and supplied to the substrate W that is immersed in the processing liquid L (S4). In step S4, at the time when the gas supply source 5 supplies gas bubbles, the controller 9 controls the first flow rate control mechanism 6. Through the steps S2 to S4, the controller 9 adjusts, on the basis of the flow rate of the processing liquid L which is supplied to the liquid discharge pipes 41 and 42, the flow rates of gas so that the flow rate of gas bubbles supplied to each of the outer gas bubble generation pipes 31 and 32 are larger than the flow rate of gas bubbles supplied to each of the inner gas bubble generation pipes 33 and 34.

### [Software Implementation Example]

Functions of the substrate processing device 100 (hereinafter, referred to as “device”) can be realized by a program for causing a computer to function as the device, the program causing the computer to function as a control block (in particular, the controller 9) of the device.

In this case, the device includes, as hardware for executing the program, a computer that includes at least one control device (e.g., a processor such as the CPU 91) and at least one storage device (e.g., the memory 92). By executing the program with the control device and the storage device, the functions described in the above embodiment are realized.

The program can be stored in at least one computer-readable non-transitory storage medium. The storage medium can be provided in the device, or the storage medium does not need to be provided in the device. In the latter case, the program can be supplied to the device via an arbitrary wired or wireless transmission medium.

Further, one or some or all of respective functions of the control block described above can be realized by a logic circuit. For example, an integrated circuit in which a logic circuit that functions as the control block described above is formed is also within the scope of the present invention.

Aspects of the present invention can also be expressed as follows:
A substrate processing device according to an aspect of the present invention includes: a substrate holder that holds at least one substrate; a process tank that stores a processing liquid for immersing therein the substrate held by the substrate holder; an outer gas bubble generation pipe that is located below a peripheral region of the substrate and that generates gas bubbles in the processing liquid by supplying gas in the processing liquid; an inner gas bubble generation pipe that is located below a central region of the substrate and that generates gas bubbles in the processing liquid by supplying gas in the processing liquid; a first gas supply pipe that connects a gas supply source and the outer gas bubble generation pipe to each other; a second gas supply pipe that connects the gas supply source and the inner gas bubble generation pipe to each other; a plurality of liquid discharge pipes that, by discharging the processing liquid into the process tank, generate an upward flow which moves upward inside the process tank; a plurality of liquid supply pipes that are connected to the plurality of liquid discharge pipes; a first flow rate control mechanism that controls flow rates of gas which is flowing in the first gas supply pipe and the second gas supply pipe; a second flow rate control mechanism that controls a flow rate of the processing liquid which is supplied to the plurality of liquid supply pipes; and a controller that controls the first flow rate control mechanism and the second flow rate control mechanism, the controller controlling, on the basis of the flow rate of the processing liquid which is controlled by the second flow rate control mechanism, the first flow rate control mechanism so that the flow rate of gas supplied to the first gas supply pipe is larger than the flow rate of gas supplied to the second gas supply pipe.

The substrate processing device in accordance with an aspect of the present invention may be configured such that the first flow rate control mechanism carries out control so that an amount of gas bubbles generated from the outer gas bubble generation pipe is larger than an amount of gas bubbles generated from the inner gas bubble generation pipe.

The substrate processing device in accordance with an aspect of the present invention may be configured such that the outer gas bubble generation pipe generates a larger number of gas bubbles than the inner gas bubble generation pipe.

The substrate processing device in accordance with an aspect of the present invention may be configured such that the outer gas bubble generation pipe, the inner gas bubble generation pipe, and the plurality of liquid discharge pipes extend along a normal direction of a main surface of the substrate; and in a state as viewed from the normal direction, the plurality of liquid discharge pipes are each provided between the outer gas bubble generation pipe and the inner gas bubble generation pipe, the upward flow generated by the plurality of liquid discharge pipes results in generation of a downward flow along a side surface of the process tank, after having reached a liquid surface of the processing liquid in the process tank, and the first flow rate control mechanism controls the flow rate of gas supplied to the first gas supply pipe so that gas bubbles generated by the outer gas bubble generation pipe move upward against the downward flow.

The substrate processing device in accordance with an aspect of the present invention may be configured such that the processing liquid contains a phosphoric acid liquid.

A substrate processing method in accordance with an aspect of the present invention includes: immersing a substrate in a processing liquid which is stored in a process tank; generating gas bubbles in the processing liquid by supplying gas to (i) an outer gas bubble generation pipe that is located below a peripheral region of the substrate which is placed in the process tank and (ii) an inner gas bubble generation pipe that is located below a central region of the substrate, and supplying the gas bubbles to the substrate which is immersed in the processing liquid; and supplying the processing liquid to a plurality of liquid discharge pipes that discharge the processing liquid in the process tank, in order to generate an upward flow which moves upward inside the process tank, the supplying the gas bubbles including performing, on the basis of a flow rate of the processing liquid which is supplied to the plurality of liquid discharge pipes, gas flow rate adjustment so that a flow rate of gas supplied to the outer gas bubble generation pipe is larger than a flow rate of gas supplied to the inner gas bubble generation pipe.

### [Additional Remarks]

The present invention is not limited to the embodiment described above, but may be altered in various ways by a skilled person within the scope of the claims. Specifically, any embodiment based on a proper combination of a plurality of technical means disclosed in the embodiment is also encompassed in the technical scope of the present invention.

### REFERENCE SIGNS LIST

100 substrate processing device
1 substrate holder
2 process tank (process bath)
2S side surface
5 gas supply source
6 first flow rate control mechanism
7 second flow rate control mechanism
9 controller (control section)
31, 32 outer gas bubble generation pipe
33, 34 inner gas bubble generation pipe
41, 42 liquid discharge pipe
51, 52 first gas supply pipe
53, 54 second gas supply pipe
71, 72 liquid supply pipe
L processing liquid
LS liquid surface
W substrate
WS main surface

1. A substrate processing device comprising:
a substrate holder that holds at least one substrate;
a process tank that stores a processing liquid for immersing therein the substrate held by the substrate holder;
an outer gas bubble generation pipe that is located below a peripheral region of the substrate and that generates gas bubbles in the processing liquid by supplying gas in the processing liquid;
an inner gas bubble generation pipe that is located below a central region of the substrate and that generates gas bubbles in the processing liquid by supplying gas in the processing liquid;
a first gas supply pipe that connects a gas supply source and the outer gas bubble generation pipe to each other;
a second gas supply pipe that connects the gas supply source and the inner gas bubble generation pipe to each other;
a plurality of liquid discharge pipes that, by discharging the processing liquid into the process tank, generate an upward flow which moves upward inside the process tank;
a plurality of liquid supply pipes that are connected to the plurality of liquid discharge pipes;
a first flow rate control mechanism that controls flow rates of gas which is flowing in the first gas supply pipe and the second gas supply pipe;
a second flow rate control mechanism that controls a flow rate of the processing liquid which is supplied to the plurality of liquid supply pipes; and
a controller that controls the first flow rate control mechanism and the second flow rate control mechanism,
the controller controlling, on the basis of the flow rate of the processing liquid which is controlled by the second flow rate control mechanism, the first flow rate control mechanism so that the flow rate of gas supplied to the first gas supply pipe is larger than the flow rate of gas supplied to the second gas supply pipe.

2. The substrate processing device according to claim 1, wherein the first flow rate control mechanism carries out control so that an amount of gas bubbles generated from the outer gas bubble generation pipe is larger than an amount of gas bubbles generated from the inner gas bubble generation pipe.

3. The substrate processing device according to claim 2, wherein the outer gas bubble generation pipe generates a larger number of gas bubbles than the inner gas bubble generation pipe.

4. The substrate processing device according to claim 1, wherein the outer gas bubble generation pipe, the inner gas bubble generation pipe, and the plurality of liquid discharge pipes extend along a normal direction of a main surface of the substrate; and
in a state as viewed from the normal direction,
the plurality of liquid discharge pipes are each provided between the outer gas bubble generation pipe and the inner gas bubble generation pipe,
the upward flow generated by the plurality of liquid discharge pipes results in generation of a downward flow along a side surface of the process tank, after having reached a liquid surface of the processing liquid in the process tank, and
the first flow rate control mechanism controls the flow rate of gas supplied to the first gas supply pipe so that gas bubbles generated by the outer gas bubble generation pipe move upward against the downward flow.

5. The substrate processing device according to claim 1, wherein the processing liquid contains a phosphoric acid liquid.

6. A substrate processing method comprising:
immersing a substrate in a processing liquid which is stored in a process tank;
generating gas bubbles in the processing liquid by supplying gas to (i) an outer gas bubble generation pipe that is located below a peripheral region of the substrate which is placed in the process tank and (ii) an inner gas bubble generation pipe that is located below a central region of the substrate, and supplying the gas bubbles to the substrate which is immersed in the processing liquid; and
supplying the processing liquid to a plurality of liquid discharge pipes that discharge the processing liquid in the process tank, in order to generate an upward flow which moves upward inside the process tank,
the supplying the gas bubbles including performing, on the basis of a flow rate of the processing liquid which is supplied to the plurality of liquid discharge pipes, gas flow rate adjustment so that a flow rate of gas supplied to the outer gas bubble generation pipe is larger than a flow rate of gas supplied to the inner gas bubble generation pipe.
